(19) United States
(12) Patent Application Publication
(10) Pub. No.: US 2026/0320462 A1
(43) Pub. Date: Oct. 15, 2026

(54) SYSTEMS AND METHODS FOR ON-CHIP ENTANGLEMENT HARVESTING

(71) Applicant: The MITRE Corporation, McLean, VA (US)

(72) Inventors: Gerald GILBERT, Princeton, NJ (US); Mark DONG, Somerville, MA (US)

(73) Assignee: The MITRE Corporation, McLean, VA (US)

(21) Appl. No.: 19/647,418

(22) Filed: Apr. 14, 2026

Related U.S. Application Data
(60) Provisional application No. 63/788,896, filed on Apr. 15, 2025.

(51) Int. Cl. G06N 10/40; H10N 30/20; H10N 39/00

(52) U.S. Cl. CPC G06N 10/40; H10N 30/2042; H10N 39/00

(57) ABSTRACT

A method for entangling qubits encoded in point defect sites in at least one solid-state host on at least one photonic integrated circuit (PIC) chip includes initializing a first qubit encoded in a first point defect site into a first quantum state, initializing a second qubit encoded in a second point defect site into the first quantum state, generating a background electromagnetic field using an electromagnetic radiation source, entangling the first and second qubit into an entanglement pair by tuning a resonance frequency of the first qubit into resonance with a resonance frequency of the background electromagnetic field for a switching time T, and after a threshold time t has elapsed, tuning a resonance frequency of the second qubit into resonance with the resonance frequency of the background electromagnetic field for the switching time T.

### CROSS-REFERENCE TO RELATED APPLICATIONS

This application claims the benefit of U.S. Provisional Application No. 63/788,896, filed Apr. 15, 2025, the entire contents of which are incorporated herein by reference.

### FIELD

The present disclosure relates generally to quantum computing systems, in particular to systems and methods for entangling qubits.

### BACKGROUND

Quantum computers perform calculations by manipulating two-state quantum mechanical systems known as qubits. Qubits, unlike classical bits, have unique physical properties that, if properly controlled by a quantum computing system, may enable the quantum computing system to solve computationally complex problems at an exponentially higher rate than classical computing systems. As a result, quantum computers are the subject of intense research interest.

Any scalable, practical quantum computing system must be capable of generating entangled qubits. A pair of entangled qubits exists in a shared quantum state; manipulating one qubit of the entangled pair instantaneously changes the other qubit of the entangled pair, even if the two qubits are spatially separated by long distances. The ability to entangle qubits is an essential requirement for any quantum computer, The ability to generate entanglement on-demand as opposed to probabilistically, is effectively a requirement, particularly for practical realizations of quantum error correction and the achievement of fault tolerance.

### SUMMARY

As discussed, quantum entanglement is an essential resource in quantum computation. Current methods of entanglement generation, however, are frequently non-deterministic—in other words, current methods do not guarantee the creation of entangled qubits one hundred percent of the time. The usual ways to deal with this typically involve significant redundancies in the quantum software and hardware design. Thus, quantum computing systems that employ existing entanglement generation methods may involve significant costs.

Accordingly, provided are deterministic techniques for generating entanglement between qubits. The described systems and methods execute an entanglement harvesting protocol that exploits the intrinsic entanglement of the virtual modes of the vacuum sector of a background electromagnetic field to entangle groups of qubits. In particular, the systems and methods may enable qubits to be entangled on-demand, which may significantly improve the utility of quantum computers in which said systems and methods are implemented.

The provided systems and methods may be configured to entangle qubits in a photonic integrated circuit (PIC) chip. These qubits may become hybrid qubits formed using the quantum states of artificial atoms established in point defect sites in a solid-state substrate on the chip (for example, nitrogen vacancy centers in diamond) as well as the quantum states of photons emitted by said defect sites and propagated along photonic channels in the chip. The entanglement harvesting process may begin by identifying a pair of spatially separate, unentangled qubits and initializing said qubits into their respective ground states. A (potentially on-chip) electromagnetic radiation source (e.g., a microwave (MW) cavity) may be used as a source of a background electromagnetic field. A resonance frequency of each qubit may be tuned into resonance with the background electromagnetic field generated by the electromagnetic radiation source at precise intervals for specific durations. The background electromagnetic field may be a resonant vacuum field such that each qubit is tuned into resonance with the resonant vacuum field. This resonance frequency tuning may cause the qubits to interact with the background electromagnetic field and due to intrinsic physical properties of the vacuum sector of the background electromagnetic field, become entangled, through the process of entanglement harvesting.

Entangling a pair of qubits as described may require management of the quantum states of the qubits. The provided systems and methods may employ on-chip devices to precisely and independently control the quantum states of qubits being entangled. In particular, piezoelectric cantilevers configured to induce mechanical strain in the solid-state host of the qubits may be used to tune the quantum states of qubits and thus, tune the resonance frequencies of the qubits during entanglement harvesting. Other parameters, including the spatial separation between the qubits being entangled, the angle between the electric field vector of the background electromagnetic field, and the spin axes of the artificial atoms, may also be carefully controlled. Entangled qubits created using the provided systems and methods may be used to transfer information between spatially separated locations, enabling the implementation quantum communication protocols such as superdense coding and quantum teleportation.

According to some embodiments, a method for entangling qubits encoded in point defect sites in at least one solid-state host on at least one photonic integrated circuit (PIC) chip includes initializing a first qubit encoded in a first point defect site into a first quantum state, initializing a second qubit encoded in a second point defect site into the first quantum state, generating a background electromagnetic field using an electromagnetic radiation source, entangling the first qubit and the second qubit into an entanglement pair by tuning a resonance frequency of the first qubit into resonance with a resonance frequency of the background electromagnetic field for a switching time T, and after a threshold time t has elapsed, tuning a resonance frequency of the second qubit into resonance with the resonance frequency of the background electromagnetic field for the switching time T.

In any of these embodiments, interacting with the entanglement pair by controlling the entangled quantum states of the first qubit and the second qubit.

In any of these embodiments, tuning the resonance frequency of the first qubit or the resonance frequency of the second qubit into resonance with the resonance frequency of the background electromagnetic field includes illuminating the first point defect site or the second point defect site with excitation light using a light source, measuring a frequency of a photon emitted by the excited first point defect site or the excited second point defect site, determining a required frequency shift based on a difference between the frequency of the emitted photon and the resonance frequency of the background electromagnetic field, and inducing a mechanical strain in the at least one solid-state host at the first point defect site or the second point defect site based on the required frequency shift. In any of these embodiments, inducing the mechanical strain in the at least one solid-state host includes applying an electric signal to a piezoelectric cantilever that is connected to the at least one solid-state host, wherein a voltage of the electric signal is based on the required frequency shift.

In any of these embodiments, the switching time T is in a range of 1 ns to 6 ns. In any of these embodiments, the switching time T is associated with at least one of a threshold separation distance r₀ between the first point defect site and the second point defect site, the resonance frequency of the background electromagnetic field, and the threshold delay time t. In any of these embodiments, the resonance frequency of the first qubit and the resonance frequency of the second qubit is in a range of 2.5 GHz to 3.0 GHz.

In any of these embodiments, the at least one solid-state host includes diamond. In any of these embodiments, the point defect sites include Group IVA defect sites. In any of these embodiments, the point defect sites include tin vacancies (SnV) or silicon vacancies (SiV). In any of these embodiments, the point defect sites include nitrogen vacancies (NV).

According to some embodiments, a system for entangling qubits includes at least one solid-state host, a first point defect site embedded in the at least one solid-state host and encoding a first qubit, a second point defect site embedded in the at least one solid-state host and encoding a second qubit, an electromagnetic radiation source configured to generate a background electromagnetic field to enable entanglement of the first qubit and the second qubit into an entanglement pair, and at least one qubit state control system configured to control quantum states of the first qubit and the second qubit to entangle the first qubit and the second qubit into the entanglement pair.

In any of these embodiments, the at least one qubit state control system is configured to entangle the first qubit and the second qubit into the entanglement pair by tuning a resonance frequency of the first qubit into resonance with a resonance frequency of the background electromagnetic field for a switching time T, and after a threshold time t has elapsed, tuning a resonance frequency of the second qubit into resonance with the resonance frequency of the background electromagnetic field for the switching time T.

In any of these embodiments, tuning the resonance frequency of the first qubit or the resonance frequency of the second qubit into resonance with the resonance frequency of the background electromagnetic field includes illuminating the first point defect site or the second point defect site with excitation light using a light source, measuring a frequency of a photon emitted by the excited first point defect site or the excited second point defect site, determining a required frequency shift based on a difference between the frequency of the emitted photon and the resonance frequency of the background electromagnetic field, and inducing a mechanical strain in the at least one solid-state host at the first point defect site or the second point defect site based on the required frequency shift.

In any of these embodiments, the at least one qubit state control system controls at least one piezoelectric cantilever that is connected to the at least one solid-state host and is configured to induce the mechanical strain in the at least one solid-state host, wherein the voltage of the electric signal applied to the piezoelectric cantilever to induce the mechanical strain is based on the required frequency shift. In any of these embodiments, the at least one qubit state control system is configured to initialize the first qubit into the first quantum state and to initialize the second qubit into the first quantum state.

In any of these embodiments, the at least one solid-state host is on at least one PIC chip. In any of these embodiments, the at least one solid-state host includes diamond. In any of these embodiments, the point defect sites embedded in the at least one solid-state host include Group IVA defect sites. In any of these embodiments, the point defect sites include tin vacancies (SnV) or silicon vacancies (SiV). In any of these embodiments, the point defect sites include nitrogen vacancies (NV).

### BRIEF DESCRIPTION OF THE FIGURES

The invention will now be described, by way of example only, with reference to the accompanying drawings.

FIG. 1 illustrates a quantum computing system, according to some embodiments.

FIG. 2 illustrates a system for entangling qubits on at least one photonic integrated circuit (PIC) chip, according to some embodiments.

FIG. 3A shows a method for entangling qubits encoded in point defect sites in at least one solid-state host on at least one photonic integrated circuit (PIC) chip, according to some embodiments.

FIG. 3B illustrates a system for entangling qubits on at least one photonic integrated circuit (PIC) chip at the start of an entanglement harvesting process, according to some embodiments.

FIG. 3C illustrates a system for entangling qubits on at least one photonic integrated circuit (PIC) chip after the unentangled qubits are initiated into their respective ground states and a background electromagnetic field has been generated, according to some embodiments.

FIG. 3D illustrates a system for entangling qubits on at least one photonic integrated circuit (PIC) chip while a pair of qubits being entangled are tuned into resonance with the background electromagnetic field, according to some embodiments.

FIG. 3E illustrates a system for entangling qubits on at least one photonic integrated circuit (PIC) chip after a pair of qubits has been entangled, according to some embodiments.

FIG. 4A illustrates an example configuration of an electromagnetic radiation source relative to at least one photonic integrated circuit (PIC) chip in a system for entangling qubits.

FIG. 4B illustrates another example configuration of an electromagnetic radiation source relative to a photonic integrated circuit (PIC) chip in a system for entangling qubits.

FIG. 5 illustrates a block diagram of a photonic integrated circuit (PIC) chip, according to some embodiments.

FIG. 6 illustrates a block diagram of a qubit state control system, according to some embodiments.

FIG. 7A illustrates a side view of a piezoelectric qubit control system, according to some embodiments.

FIG. 7B illustrates deformations of a solid-state waveguide induced by deflections of a piezoelectric cantilever, according to some embodiments.

FIG. 8 shows a method for controlling a quantum state of a qubit encoded in point defect sites in at least one solid-state host on at least one photonic integrated circuit (PIC) chip using a piezoelectric cantilever, according to some embodiments.

FIG. 9 illustrates a system, according to some embodiments, for entangling qubits using a piezoelectric cantilever.

### DETAILED DESCRIPTION

The utility of a quantum computer hinges in part upon the quantum computer's ability to create and utilize entangled qubits. The described systems and methods provide a deterministic solution for entangling qubits (e.g., such as, entangling a first qubit and a second qubit into an entanglement pair). In addition to significantly increasing the quantum computing processing power and processing speed, the systems and methods provided herein may enable users to entangle qubits on-demand, potentially increasing the efficiency and ease with which quantum algorithms can be developed and executed.

To generate entangled qubits, the provided systems and methods may use an entanglement harvesting protocol wherein initially unentangled qubits are forced into an entangled state by interacting with the same background electromagnetic field. The qubits being entangled may be hybrid qubits comprising a combination of the quantum states of artificial atoms established in point defect sites in at least one solid-state substrate on at least one photonic integrated circuit (PIC) chip (for example, nitrogen vacancy centers in diamond) and the quantum states of photons emitted by the defect sites. Any pair of unentangled qubits that meet certain criteria (e.g., separation distance limits or temporal limits) may be entangled by interacting said qubits with a background electromagnetic field generated by an electromagnetic radiation source (e.g., a microwave (MW) cavity). The qubits may interact with the background electromagnetic field by tuning resonance frequencies of the qubits into resonance with a resonance frequency of the background electromagnetic field in accordance with a set of predetermined entanglement parameters. The background electromagnetic field may be a resonant vacuum field such that the qubits are tuned into resonance with the resonant vacuum field. Devices on the at least one PIC chip may facilitate the precise and independent control of quantum states of qubits being entangled. Entangled qubits created using the provided systems and methods may be used in a variety of applications, including quantum communication protocols such as superdense coding and quantum teleportation.

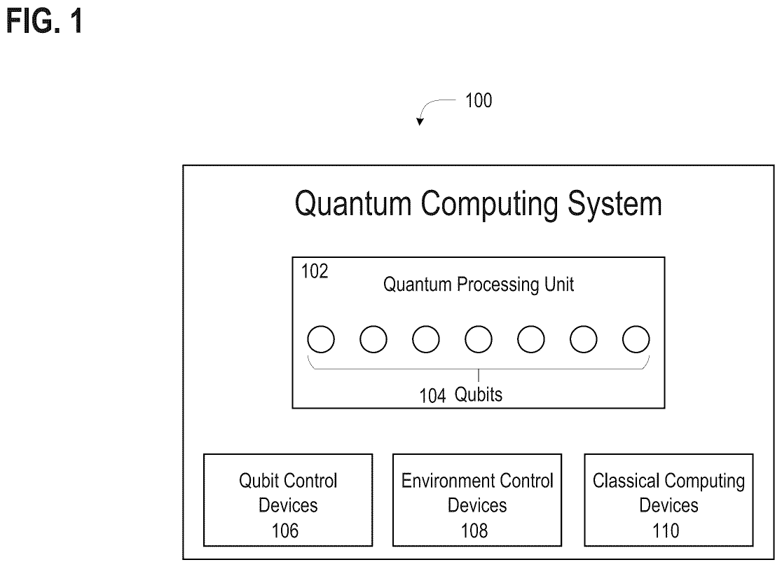

An exemplary quantum computing system 100 is illustrated in FIG. 1. As shown, quantum computing system 100 may be a device comprising a quantum processing unit (QPU) 102 that is configured to perform computational operations by encoding information in and manipulating the quantum states of one or more qubits 104. Each qubit 104 may be a two-state quantum mechanical system. Possible implementations of qubits 104 can include, in non-limiting examples, electrons (e.g., electron spin qubits), photons (e.g., polarization encoding or time bin encoding qubits), atomic nuclei (e.g., nuclear spin encoded qubits), quantum dots, Josephson junctions (e.g., flux qubits), and solid-state defects (e.g., nitrogen vacancy centers in diamond).

To facilitate the encoding and manipulation of information, quantum computing system 100 may include devices 106 for controlling qubits 104 such as lasers, microwave radiation sources, voltage sources, current sources, digital-to-analog converters, application specific integrated circuits (ASICs), and field programmable gate arrays (FPGAs). In some embodiments, one or more qubit control devices 106 may be components of QPU 102. Additionally, quantum computing system 100 may include any environmental control devices 108 necessary to stabilize qubits 104. Environmental control devices 108 may, for example, include one or more temperature controllers configured to control the temperature of an environment of qubits 104. Quantum computing system 100 can also include one or more classical computing devices 110 (e.g., CPUs or GPUs) configured to interface with QPU 102 to (for example) compile instructions for a given quantum algorithm to be executed by the QPU 102 or process quantum-state measurements after a quantum algorithm is executed.

A system for entangling qubits may be implemented in a quantum computing system such as quantum computing system 100. The system may be configured to execute an entanglement harvesting protocol to entangle groups of qubits in a quantum processing unit (e.g., qubits 104 in QPU 102 shown in FIG. 1). The entanglement may be deterministic and, in some embodiments, achieved on-demand, for example upon receipt of instructions in a quantum algorithm provided by a user.

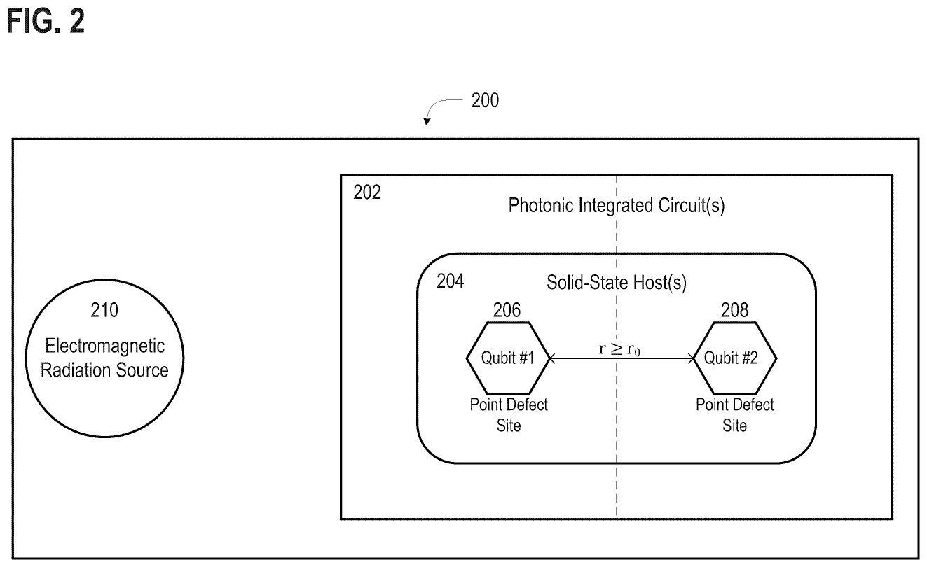

FIG. 2 depicts an exemplary system 200 for entangling qubits. As shown, system 200 may comprise at least one photonic integrated circuit (PIC) chip 202 as well as an electromagnetic radiation source 210 configured to generate a background electromagnetic field. System 200 may be implemented in a quantum computing system such as quantum computing system 100 shown in FIG. 1. For example, system 200 may be a component of QPU 102.

PIC chip 202 may include at least one solid-state host 204. Solid-state host 204 may, for example, be formed from diamond or silicon carbide. Embedded in solid-state host 204 may be a plurality of point defect sites. Each point defect site may be a location in the atomic lattice of solid-state host 204 at which at least an atom that is dissimilar from the atoms that make up the material that constitutes solid-state host 204 has been (artificially or naturally) implanted. For example, if solid-state host 204 is formed from diamond, then a point defect site in solid-state host 204 may be a location in the diamond lattice at which a non-carbon atom has been implanted. The location at which the dissimilar atom is implanted may be a location at which an imperfection or a vacancy in the atomic lattice of solid-state host 204 arose, for example as a result of natural variations in the lattice or as a result of artificial introduction by an external source. Example atoms that may be implanted in solid-state host 204 to create a point defect site include nitrogen atoms (e.g., nitrogen vacancy (NV) centers in a diamond host) and group IVA atoms (e.g., silicon vacancy (SiV) or tin vacancy (SnV) centers in a diamond host).

Each point defect site in solid-state host 204 may form an “artificial atom” that has free electrons. Upon absorption of excitation light at appropriate frequencies, the free electrons at a point defect site may jump from a low energy ground state to a higher energy excited state. The excited electrons may then return to their ground states and may emit photons in the process. The quantum state (e.g., the spin state) of an artificial atom in a point defect site, as well as the quantum states of photons emitted by the artificial atom, may be used to form a qubit. Such a qubit may be encoded in each point defect site in solid-state host 204.

In addition to solid-state host 204, PIC chip 202 can also include components for facilitating the transmission of electronic or optical signals (e.g., photonic channels or conductive traces), microwave radiation sources, voltage sources, current sources, digital-to-analog converters, application specific integrated circuits (ASICs), field programmable gate arrays (FPGAs), or any other devices for controlling or manipulating the qubits encoded in the point defect sites in solid-state host 204.

To entangle a pair of qubits encoded in point defect sites in solid-state host 204, system 200 may be configured to execute an entanglement harvesting protocol. The entanglement harvesting protocol exploits a consequence of the Reeh-Schlieder theorem (published by physicists Helmut Reeh and Siegfried Schleider in 1961) which indicates that the virtual modes of the vacuum state of a quantum field are highly entangled. That is,

|0 [symbol] _{f}≠⊗|0 [symbol] _{f, n}

where |0 [symbol] _{f} represents the vacuum state of a quantum field, |0 [symbol] _{f, n} represents the n-th virtual mode of the vacuum state of the quantum field, and ⊗ represents a tensor product. Given a switching time T and a temporal delay time t, a pair of unentangled particles immersed in a quantum field may become entangled due to the entanglement of the virtual modes of the vacuum state of said quantum field—i.e., the unentangled particles may “harvest” some of the entanglement that is intrinsic to the background quantum field.

In system 200, the particles to be entangled may be qubits encoded in point defect sites in solid state host 204, and the background quantum field from which the qubits “harvest” entanglement may be the background electromagnetic field generated by the electromagnetic radiation source 210. Electromagnetic radiation source 210 may be a microwave (MW) cavity. The background electromagnetic field generated by the electromagnetic radiation source 210 may have a vacuum cavity frequency (e.g., resonance frequency of the background electromagnetic field) closely matched (e.g., to within 10 s of MHz) to the resonance frequency of the qubits encoded in the point defect sites. In some embodiments, a resonance frequency of the qubits encoded in point defect sites is 2.87 GHz, thus the vacuum cavity frequency (e.g., resonance frequency of the background electromagnetic field) is between 2.80 GHz and 2.94 GHz, for example approximately 2.81 GHz, 2.82 GHz, 2.83 GHz, 2.84 GHz, 2.85 GHz, 2.86 GHz, 2.87 GHz, 2.88 GHz, 2.89 GHz, 2.90 GHz, 2.91 GHz, 2.92 GHz, or 2.93 GHz. In some embodiments, the vacuum cavity frequency is greater than or equal to 2.81 GHz, 2.82 GHz, 2.83 GHz, 2.84 GHz, 2.85 GHz, 2.86 GHz, 2.87 GHz, 2.88 GHz, 2.89 GHz, 2.90 GHz, 2.91 GHz, 2.92 GHz, or 2.93 GHz. In some embodiments, the vacuum cavity frequency is less than or equal to 2.81 GHz, 2.82 GHz, 2.83 GHz, 2.84 GHz, 2.85 GHz, 2.86 GHz, 2.87 GHz, 2.88 GHz, 2.89 GHz, 2.90 GHz, 2.91 GHz, 2.92 GHz, or 2.93 GHz.

As noted, certain conditions may need to be met in order for a pair of unentangled qubits to be entangled using an entanglement harvesting protocol. One such condition may be the spatial separation of the unentangled qubits. In order for a first qubit encoded in a first point defect site 206 and a second qubit encoded in a second point defect site 208 to be entangled, the second point defect site 208 may need to exceed a threshold separation distance r₀ of the first point defect site 206. The threshold separation distance may depend upon the background electromagnetic field generated by the electromagnetic radiation source 210 (e.g., such as, the resonance frequency of the background electromagnetic field), a switching time T, or a temporal delay time t between an interaction of the first point defect site 206 with the background electromagnetic field and the interaction of the second point defect site 208 with the background electromagnetic field. The threshold separation distance may also depend upon the number of unentangled qubits. In some embodiments, the threshold separation distance r₀ is between about 1 m and 10 m, for example approximately 0.5 m, 1 m, 1.5 m, 2 m, 2.5 m, 3 m, 3.5 m, 4 m, 4.5 m, 5 m, 5.5 m, 6 m, 6.5 m, 7 m, 7.5 m, 8 m, 8.5 m, 9 m, 9.5 m, 10 m, or 10.5 m. In some embodiments, the threshold separation distance r₀ is greater than or equal to 0.5 m, 1 m, 1.5 m, 2 m, 2.5 m, 3 m, 3.5 m, 4 m, 4.5 m, 5 m, 5.5 m, 6 m, 6.5 m, 7 m, 7.5 m, 8 m, 8.5 m, 9 m, 9.5 m, 10 m, or 10.5 m. In some embodiments, the threshold separation distance r₀ is less than or equal to 0.5 m, 1 m, 1.5 m, 2 m, 2.5 m, 3 m, 3.5 m, 4 m, 4.5 m, 5 m, 5.5 m, 6 m, 6.5 m, 7 m, 7.5 m, 8 m, 8.5 m, 9 m, 9.5 m, 10 m, or 10.5 m. In some embodiments, the threshold separation distance r₀ is between 10 cm and 50 cm, for example approximately 5 cm, 15 cm, 25 cm, 35 cm, 45 cm, or 55 cm. In some embodiments, the threshold separation distance r₀ is greater than or equal to 5 cm, 15 cm, 25 cm, 35 cm, 45 cm, or 55 cm. In some embodiments, the threshold separation distance r₀ is less than or equal to 5 cm, 15 cm, 25 cm, 35 cm, 45 cm, or 55 cm. In some embodiments, the threshold separation distance r₀ is between 5 mm and 50 mm, for example approximately 1 mm, 10 mm, 20 mm, 30 mm, 40 mm, 50 mm, or 55 mm. In some embodiments, the threshold separation distance r₀ is greater than or equal to 1 mm, 10 mm, 20 mm, 30 mm, 40 mm, 50 mm, or 55 mm. In some embodiments, the threshold separation distance r₀ is less than or equal to 1 mm, 10 mm, 20 mm, 30 mm, 40 mm, 50 mm, or 55 mm.

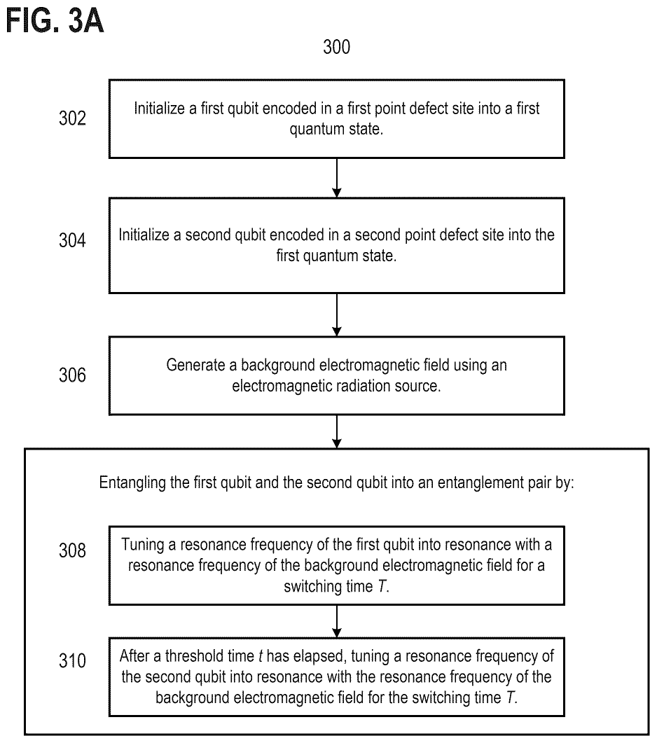

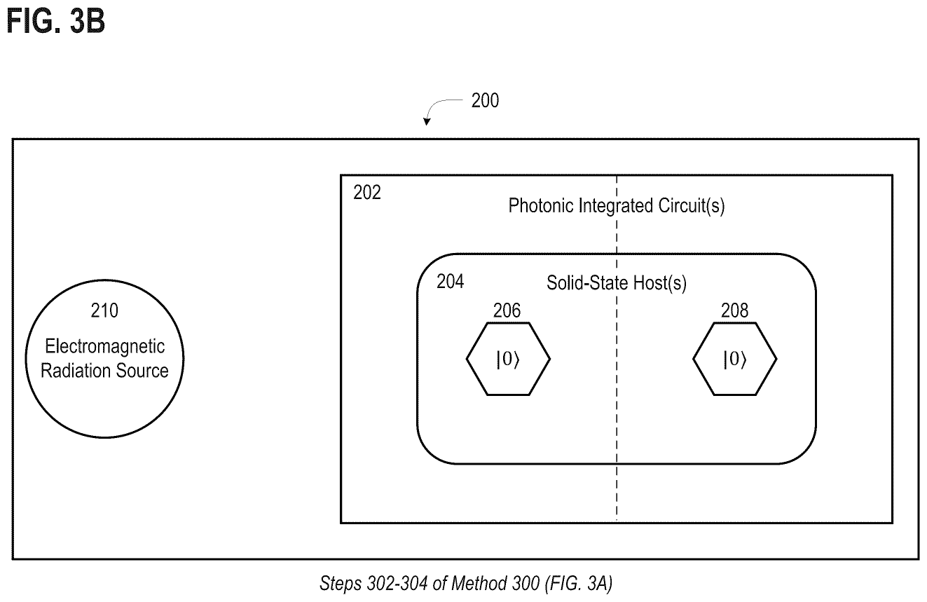

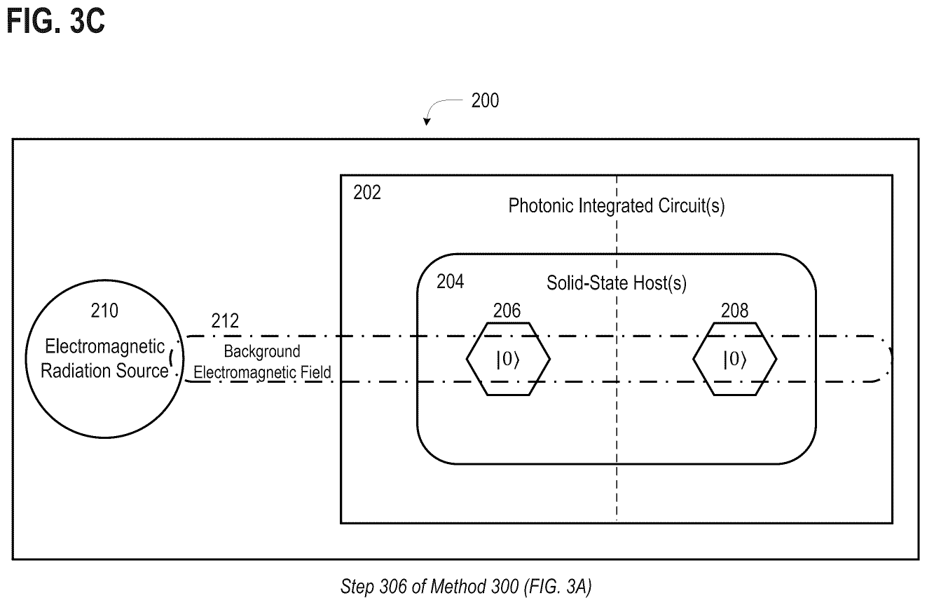

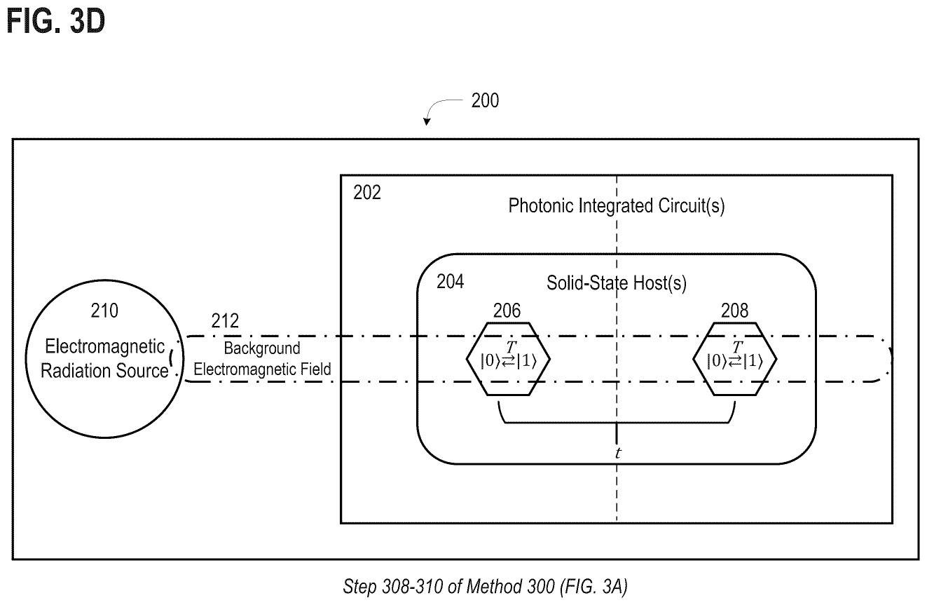

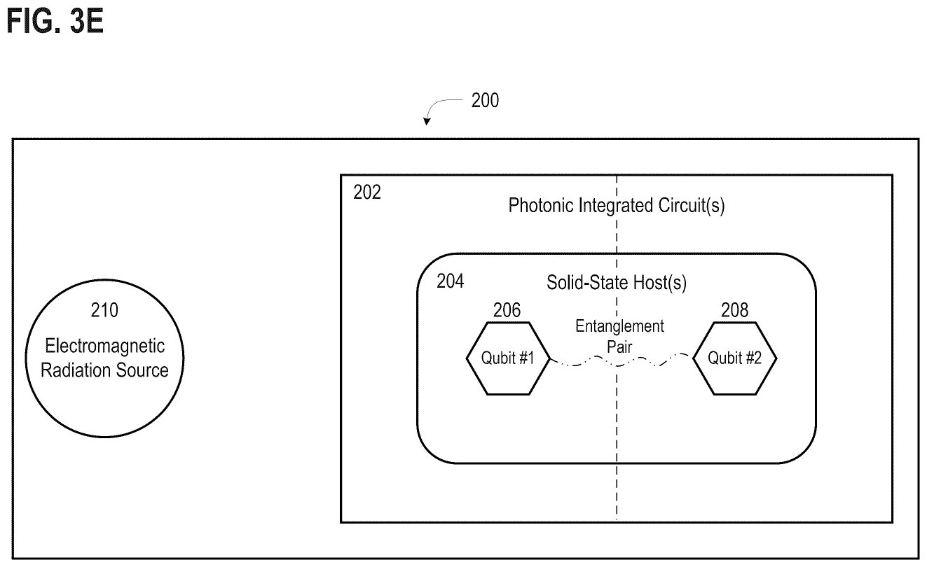

Once a pair of unentangled qubits that meet the separation criterion are identified, system 200 may execute an entanglement harvesting protocol to entangle the pair. FIG. 3 provides an exemplary method 300 for entangling a pair of qubits using a system such as system 200. Illustrations of system 200 during the execution of various steps of method 300 are provided in FIGS. 3B-3E.

The entanglement harvesting process may begin by initializing the first qubit of the pair of unentangled qubits into a first quantum state (step 302, FIG. 3B). This first quantum state may be a ground state (represented as |0 [symbol] in FIG. 3B) of the first qubit. The first qubit may be initialized into the first quantum state using a light source, which may emit photons of a wavelength less than the photon emission wavelength of the qubit. The light source may be a laser. In some embodiments, the laser photon emission wavelength is between 500 nm and 600 nm, for example approximately 490 nm, 500 nm, 510 nm, 520 nm, 530 nm, 532 nm, 540 nm, 550 nm, 560 nm, 570 nm, 580 nm, 590 nm, 600 nm, or 610 nm. In some embodiments, the laser photon emission wavelength is 532 nm due to commercial availability of 532 nm laser sources. The second qubit of the pair of unentangled qubits may also be initialized into the first quantum state using the same laser system as described above (step 304, FIG. 3B). The resulting quantum system (comprising the first qubit in the first quantum state and the second qubit in the first quantum state) may be a separable (i.e., non-entangled) bipartite system.

After initializing the first and second qubits into the first quantum state, a background electromagnetic field (e.g., background electromagnetic field 212 shown in FIG. 3C) may be generated by the electromagnetic radiation source 210 (step 306, FIG. 3C). In some embodiments, the background electromagnetic field may be generated (e.g., present) during step 302 and step 304. In some embodiments, the background electromagnetic field may be generated (e.g., present) prior to step 302 and step 304. The resulting quantum system (comprising the separable bipartite system of the first and second qubits and the vacuum sector of the background electromagnetic field) may be a separable (i.e., non-entangled) tripartite system.

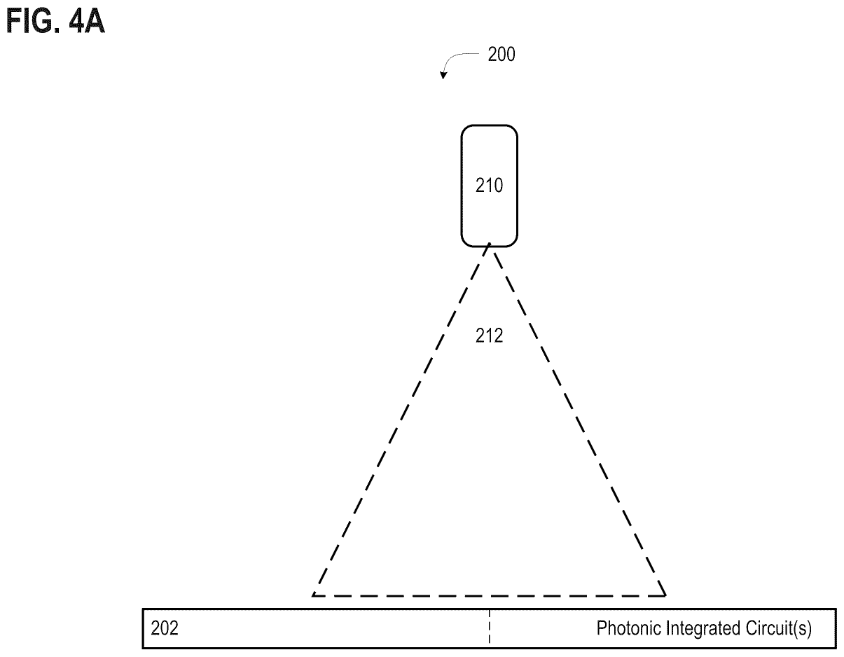

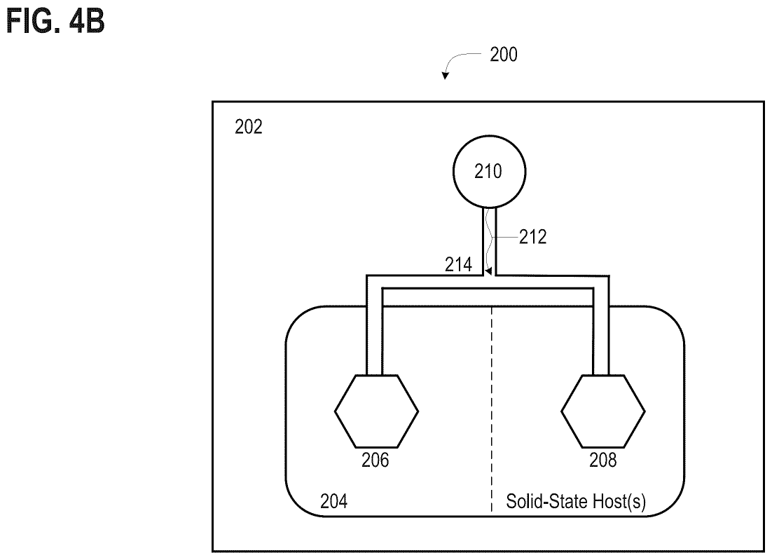

In some embodiments of system 200, as shown in FIG. 4A, the electromagnetic radiation source 210 is positioned above PIC chip 202 so that the background electromagnetic field 212 encompasses the first and second point defect sites. In other embodiments, as shown in FIG. 4B, the electromagnetic radiation source 210 is a component of PIC chip 202, and the background electromagnetic field 212 may be transmitted to the first point defect site 206 and the second point defect site 208 by a network of photonic couplers 214. In some embodiments, the system 200 includes a plurality of electromagnetic radiation sources, such as a plurality of electromagnetic radiation sources 210. Each electromagnetic radiation source may generate a background electromagnetic field (e.g., such as background electromagnetic field 212) with at least one common resonance frequency, and each background electromagnetic field may encompass a point defect site. For instance, the system 200 may include a first electromagnetic radiation source (e.g., such as electromagnetic radiation source 210) that generates a first background electromagnetic field with a resonance frequency A, and the first background electromagnetic field may encompass the first point defect site 206. The system 200 may include a second electromagnetic radiation source (e.g., such as electromagnetic radiation source 210) that generates a second background electromagnetic field with a resonance frequency A, and the second background electromagnetic field may encompass the second point defect site 208. In any case, the system may be configured such that an angle between an electric field vector of the background electromagnetic field and a spin axis of the first and second qubits is minimal, such that a value of a projection of the electric field vector onto the spin axis of the first and second qubits is maximal. This angle may be another condition that must be met in order for the first and second qubits to harvest entanglement from the background electromagnetic field. In some embodiments, the angle is between 0° and 10°, for example approximately 1°, 2°, 3°, 4°, 5°, 6°, 7°, 8°, or 9°. Additionally, the angle between the spin axis of the first qubit and the spin axis of the second qubit may be configured. This angle may be another condition that must be met in order for the first and second qubits to harvest entanglement from the background electromagnetic field.

A resonance frequency of the first qubit and the second qubit may be tuned into resonance with a resonance frequency of the background electromagnetic field (step 308 and step 310, FIG. 3D). The resonance frequency of the first qubit and the second qubit may be tuned by adjusting an energy of a second quantum state of the first qubit and the second qubit. This second quantum state (represented as |1 [symbol] in FIG. 3D) may have a higher energy than the first quantum state—in other words, the second quantum state may be a higher energy state generated by spin-orbit coupling, Zeeman interaction, or hyperfine coupling. The higher energy state may also be an excited state of the first qubit and the second qubit. In some embodiments, the resonance frequency of the first qubit and the second qubit (e.g., frequency difference between the first quantum state and the second quantum state) is between 2.5 GHz and 3.0 GHz, for example approximately 2.55 GHz, 2.60 GHz, 2.65 GHz, 2.70 GHz, 2.75 GHz, 2.80 GHz, 2.85 GHz, 2.87 GHz, 2.90 GHz, or 2.95 GHz; 2.87 GHz may be the resonance frequency of the first qubit and the second qubit (e.g., frequency difference between the first quantum state and the second quantum state) for point defect sites comprised of NV centers. A person of skill in the art will appreciate that the resonance frequency of the first qubit may be the same, or different, as the resonance frequency of the second qubit. The resonance frequency of the first qubit and the second qubit may be tuned into resonance with the resonance frequency of the background electromagnetic field a switching time T. In some embodiments, the switching time T is between about 1 ns and 6 ns, for example approximately 0.5 ns, 1 ns, 1.5 ns, 2 ns, 2.5 ns, 3 ns, 3.5 ns, 4 ns, 5 ns, 5.5 ns, 6 ns, or 6.5 ns. In some embodiments, the switching time T is greater than or equal to 0.5 ns, 1 ns, 1.5 ns, 2 ns, 2.5 ns, 3 ns, 3.5 ns, 4 ns, 5 ns, 5.5 ns, 6 ns, or 6.5 ns. In some embodiments, the switching time T is less than or equal to 0.5 ns, 1 ns, 1.5 ns, 2 ns, 2.5 ns, 3 ns, 3.5 ns, 4 ns, 5 ns, 5.5 ns, 6 ns, or 6.5 ns. As the first and second qubit are tuned into resonance with the background electromagnetic field (e.g., the resonance frequency of the first and second qubit is tuned into resonance with the resonance frequency of the background electromagnetic field) for the switching time T, the first and second qubit may interact with the background electromagnetic field. The first and second qubits may be tuned out of resonance with the background electromagnetic field after the switching time T by adjusting the energy of the second quantum state of the first qubit and the second qubit.

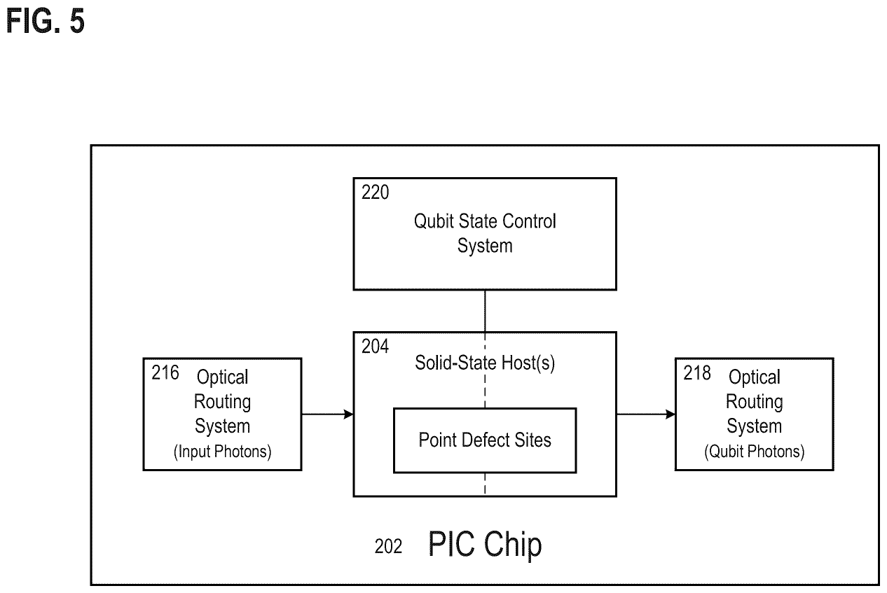

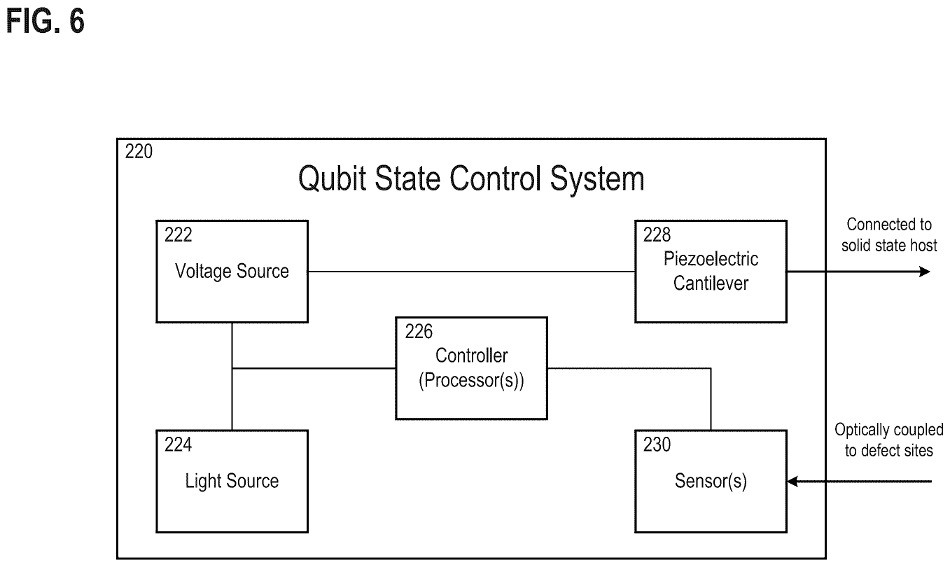

The first qubit and the second qubit may be independently tuned into resonance with the background electromagnetic field. In some embodiments, the first qubit is tuned into resonance with the background electromagnetic field for the switching time T (step 308, method 300), and after a threshold delay time t has elapsed, the second qubit is tuned into resonance with the background electromagnetic field for the switching time T (step 310, method 300). This threshold delay time t may be tracked using a qubit state control system 220, as shown in FIG. 5 and FIG. 6. In some embodiments, the threshold delay time t is between approximately 10 ns and 60 ns, for example about 5 ns, 10 ns, 15 ns, 20 ns, 25 ns, 30 ns, 35 ns, 40 ns, 45 ns, 50 ns, 55 ns, 60 ns, or 65 ns. In some embodiments, the threshold delay time t is greater than or equal to 5 ns, 10 ns, 15 ns, 20 ns, 25 ns, 30 ns, 35 ns, 40 ns, 45 ns, 50 ns, 55 ns, 60 ns, or 65 ns. In some embodiments, the threshold delay time t is less than or equal to 5 ns, 10 ns, 15 ns, 20 ns, 25 ns, 30 ns, 35 ns, 40 ns, 45 ns, 50 ns, 55 ns, 60 ns, or 65 ns. The switching time T and the threshold delay time t may be associated with the entangling of the first qubit and the second qubit. Specifically, the tuning of the first qubit into resonance with the background electromagnetic field and the tuning of the second qubit into resonance with the background electromagnetic field after the threshold delay time has elapsed may correspond to an amount of interaction between the first and second qubits and the background electromagnetic field that is sufficient to entangle the first qubit and the second qubit into the entanglement pair (i.e., an inseparable, bipartite system) (FIG. 3E). Thus, once the entanglement pair has been created, the entanglement pair may be included or operated in subsequent systems and methods. For instance, the entanglement pair may be included in a quantum computing system (e.g., a quantum computer), and the entangled quantum states of the entanglement pair included in the quantum computing system may be controlled or monitored. In some embodiments, the first qubit and the second qubit are simultaneously tuned into resonance with the background electromagnetic field for the switching time T, such that tuning the qubits simultaneously into resonance with the background electromagnetic field corresponds to an amount of interaction between the qubits and the background electromagnetic field that is sufficient to entangle the qubits into the entanglement pair.

Precise control of the quantum states of qubits being entangled may be essential to executing a method such as method 300. This control may be facilitated by various components of the PIC chip. As shown in FIG. 5, PIC chip 202 of system 200 may include (in addition to the at least one solid-state host 204) an optical routing system 216 configured to transmit photons to qubits encoded in point defect sites in solid state host 204, an optical routing system 218 configured to transmit qubit photons (i.e., photons emitted by point defect sites in solid state host 204) to other components of a quantum computing system, and a qubit state control system 220 configured to directly control the quantum states of the qubits.

Qubit state control system 220 may be any device or collection of devices configured to monitor and control the quantum states of qubits encoded in point defect sites in solid state host 204. Qubit state control system 220 may be configured to tune resonance frequencies of qubits into resonance with a background electromagnetic field for at least the switching time T necessary to achieve entanglement (see, e.g., step 308 and step 310 in method 300). For instance, the qubit state control system 220 may be configured to tune a resonance frequency of a first qubit into resonance with a resonance frequency of the background electromagnetic field for a switching time T. After a threshold time t has elapsed, the qubit state control system 220 may be configured to tune a resonance frequency of a second qubit into resonance with the resonance frequency of the background electromagnetic field for the switching time T. In some embodiments, qubit state control system 220 may comprise a light source 224, wherein the light source 224 is configured to initialize the qubits into the first quantum state, such as discussed above in reference to step 302 and step 304 in method 300 (FIG. 3), or is configured to emit excitation light to excite qubits. Light source 224 may be a laser, such as any other laser described herein.

In some embodiments, as shown in FIG. 6, qubit state control system 220 is a piezoelectric strain control system. In this implementation, qubit state control system 220 may comprise at least one piezoelectric cantilever 228 that is connected to the solid-state host. When a voltage is applied to piezoelectric cantilever 228 by a voltage source 222, piezoelectric cantilever 228 may deflect or curl away from an equilibrium (e.g., zero applied voltage) position. The displacement of piezoelectric cantilever 228 may cause the solid-state host to mechanically deform and may induce a mechanical strain at one or more of the point defect sites embedded in the solid-state host. This mechanical strain may shift the energy levels of the artificial atom(s) at the affected point defect sites by an amount that depends directly on the amount of strain at the defect site. Therefore, by controlling the amount of strain induced at a defect site, the quantum state of the qubit encoded in said defect site may be tuned, and thus, a resonance frequency of the qubit may be tuned.

Other devices in addition to voltage source 222 and piezoelectric cantilever 228 may be included in a piezoelectric strain control system. These devices include the light source 224; sensors 230, which may be configured to detect frequencies of photons emitted by the artificial atoms in the solid-state host in order to gain insight into the quantum states of the qubits; and a controller 226 (which may include one or more processors and memory storing instructions for executing one or more programs for providing the functionality described herein), which may be configured to control voltage source 222, light source 224, and sensors 230.

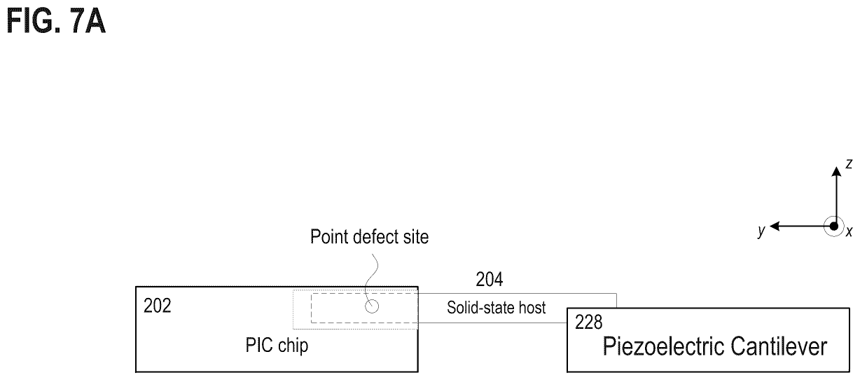

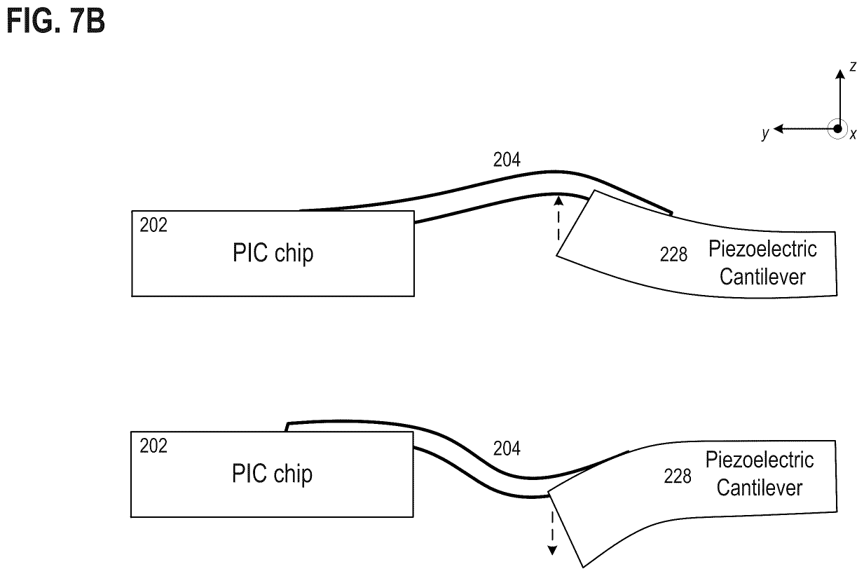

In some embodiments, as shown in FIG. 7A, solid state-host 204 may be suspended between the piezoelectric cantilever 228 and (a portion of) PIC chip 202. Solid-state host 204 may be optically coupled to PIC chip 202 and mechanically coupled to piezoelectric cantilever 228. When no voltage is applied to piezoelectric cantilever 228, cantilever 228 and, as a result, solid-state host 204 may be undeformed, and the point defect site(s) in solid state host 204 may be unstrained. However, when a voltage is applied to piezoelectric cantilever 228, piezoelectric cantilever 228 may deflect away from its zero-voltage position. For example, if the zero-voltage position of piezoelectric cantilever 228 is parallel to the x-y plane defined in FIG. 7A, then applying a voltage to piezoelectric cantilever 228 may cause piezoelectric cantilever 228 to deflect in a direction perpendicular to the x-y plane (e.g., the +z direction or −z direction), as shown in FIG. 7B.

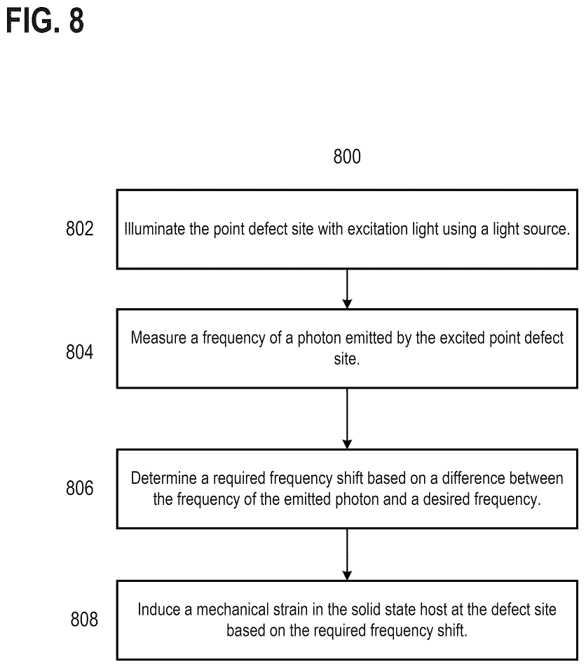

FIG. 8 provides a method 800 for tuning a resonance frequency of a qubit using a piezoelectric strain control system such as the system illustrated in FIG. 6 and FIGS. 7A-7B. The point defect site in which the qubit is encoded may first be illuminated with excitation light using a light source, such as discussed above in reference to qubit state control system 220 (e.g., light source 224 shown in FIG. 6) (step 802). The excited artificial atom may emit a photon, the frequency of which may be measured (e.g., using sensor 230 shown in FIG. 6) (step 804). A required frequency shift may be determined (e.g., by controller 226 shown in FIG. 6) based on a difference between the frequency of the emitted photon and a desired frequency (step 806), for instance, a resonance frequency of a background electromagnetic field, such as described herein. The frequency shift may be used to determine a voltage to be applied to a piezoelectric cantilever that is connected to the solid-state host of the qubit. Applying this voltage to the cantilever may induce a mechanical strain in the solid-state host at the defect site that causes the energy levels of the artificial atom to shift by an amount corresponding to the required frequency shift (step 808).

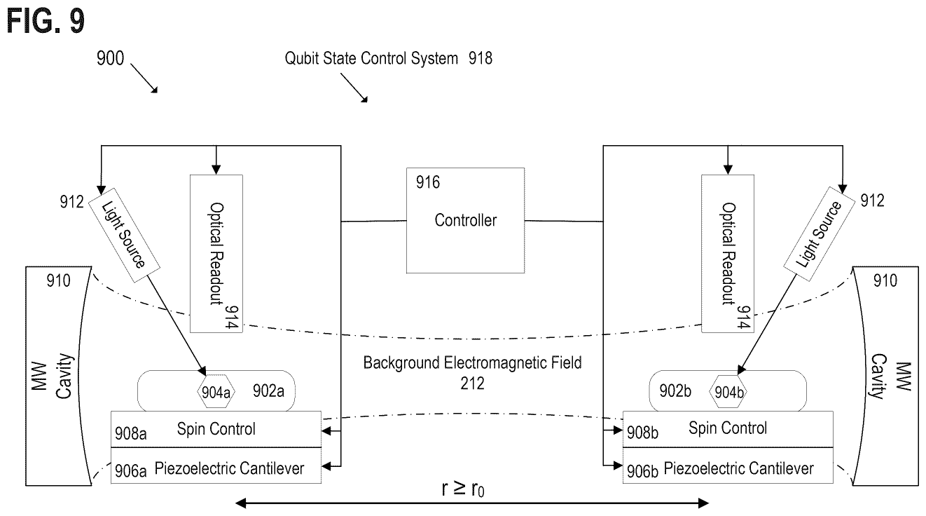

FIG. 9 illustrates a system 900 for entangling qubits, according to some embodiments. System 900 may include a first solid-state host 902a embedded with a first point defect site 904a that encodes a first qubit. System 900 may include a second solid-state host 902b embedded with a second point defect site 904b that encodes a second qubit. The solid-state host 902a and the solid-state host 902b may be any of the solid-state hosts described herein, such as solid-state host 204. The first point defect site 904a and the second point defect site 904b may be any of the point defect sites as described herein, such as the first point defect site 206 and the second point defect site 208, respectively. The first point defect site 904a and the second point defect site 904b may be separated by a distance greater than or equal to the threshold separation distance r₀. System 900 may include a qubit state control system 918 for controlling quantum states of the first and second qubits. Qubit state control system 918 may be any of the qubit state control systems described herein, such as qubit state control system 220 of FIG. 6. Qubit state control system 918 may include a controller 916. The controller 916 may be any of the controllers described herein, such as the controller 226. Qubit state control system 918 may include a first piezoelectric cantilever 906a and a second piezoelectric cantilever 906b. Piezoelectric cantilever 906a and piezoelectric cantilever 906b may be controlled by controller 916 (e.g., via a suitable voltage source, such as voltage source 222 of FIG. 6). The first piezoelectric cantilever 906a and the second piezoelectric cantilever 906b may be any of the piezoelectric cantilevers described herein, such as the piezoelectric cantilever 228. For example, the first piezoelectric cantilever 906a and the second piezoelectric cantilever 906b may be configured to tune resonance frequencies of the first qubit and the second qubit by inducing mechanical strain in the first solid-state host 902a and the second solid-state host 902b, respectively, such as described in method 800 of FIG. 8.

Qubit state control system 918 may include a first spin control device 908a and a second spin control device 908b. The first spin control device 908a and the second spin control device 908b may be configured to emit microwave radiation, which may excite the qubits to a higher energy quantum state. The first spin control device 908a and the second spin control device 908b may be any device configured to emit microwave radiation. In some embodiments, the spin control device 908a and 908b is a microwave antenna that is controlled by controller 916. In some embodiments, the spin control device 908a and 908b is a PIC chip, which may be any of the PIC chips described herein, such as PIC 202 in FIG. 2. The first spin control device 908a may be on the first piezoelectric cantilever 906a, and the second spin control device 908b may be on the second piezoelectric cantilever 906b. The first solid-state host 902a may in turn be on the first spin control device 908a, and the second solid-state host 902b may in turn be on the second spin control device 908b.

The background electromagnetic field 212 may be generated by a microwave cavity 910. A light source 912 may be configured to initialize the qubits into the first quantum state, as discussed above in reference to step 302 and step 304 in method 300 (FIG. 3). The light source 912 may include at least one 532 nm laser, or any other suitable laser, including any laser described herein. In some embodiments, the qubit state control system 918 is comprised of light source 912. Light source 912 may also be any of the other light sources as described herein, such as light source 224 in FIG. 6. In some embodiments, the light source 912 is controlled by controller 916. An optical readout system 914 may be configured to optically detect a frequency and/or a magnitude of photons emitted by the qubits to gain insight into the quantum states of the qubits. The optical readout system 914 may include any components configured to optically detect the frequency and/or magnitude of photons emitted by the qubits. For example, the optical readout system 914 may include at least one mirror, at least one lens, at least one camera, at least one photodiode, at least one density filter, at least one beamsplitter, at least one bandpass filter, at least one attenuator, at least one polarizer, and/or any other component configured to optically detect the frequency and/or magnitude of photons emitted by the qubits. In some embodiments, the qubit state control system 918 is comprised of the optical readout system 914. The optical readout system 914 may be any of the other optical readout systems as described herein, such as sensor 230 in FIG. 6. In some embodiments, the optical readout system 914 is controlled by controller 916.

In some embodiments, the entanglement protocols described herein may be used to entangle more than two qubits. The properties associated with the entanglement protocols described herein, such as the threshold separation distance r₀, the switching time T, the threshold delay time t, and/or the resonance frequency of the background electromagnetic field, may be associated with the number of qubits being entangled.

In some examples, the qubits entangled by protocols described herein may be a component for quantum computing; quantum computing protocols may perform computations too complex and/or too time-intensive for classical computation. Entangled qubits may enable quantum communication, wherein quantum information (e.g., the quantum state) is transferred between entangled qubits that are spatially separated. For example, a quantum communication protocol may be quantum teleportation or superdense coding.

1. A method for entangling qubits encoded in point defect sites in at least one solid-state host on at least one photonic integrated circuit (PIC) chip, the method comprising:
initializing a first qubit encoded in a first point defect site into a first quantum state;
initializing a second qubit encoded in a second point defect site into the first quantum state;
generating a background electromagnetic field using an electromagnetic radiation source; and
entangling the first qubit and the second qubit into an entanglement pair by tuning a resonance frequency of the first qubit into resonance with a resonance frequency of the background electromagnetic field for a switching time T, and after a threshold time t has elapsed, tuning a resonance frequency of the second qubit into resonance with the resonance frequency of the background electromagnetic field for the switching time T.

2. The method of claim 1, comprising interacting with the entanglement pair by controlling entangled quantum states of the first qubit and the second qubit.

3. The method of claim 1, wherein tuning the resonance frequency of the first qubit or the resonance frequency of the second qubit into resonance with the resonance frequency of the background electromagnetic field comprises:
illuminating the first point defect site or the second point defect site with excitation light using a light source;
measuring a frequency of a photon emitted by the excited first point defect site or the excited second point defect site;
determining a required frequency shift based on a difference between the frequency of the emitted photon and the resonance frequency of the background electromagnetic field; and
inducing a mechanical strain in the at least one solid-state host at the first point defect site or the second point defect site based on the required frequency shift.

4. The method of claim 3, wherein inducing the mechanical strain in the at least one solid-state host comprises applying an electric signal to a piezoelectric cantilever that is connected to the at least one solid-state host, wherein a voltage of the electric signal is based on the required frequency shift.

5. The method of claim 1, wherein the switching time T is in a range of 1 ns to 6 ns.

6. The method of claim 1, wherein the switching time T is associated with at least one of a threshold separation distance r₀ between the first point defect site and the second point defect site, the resonance frequency of the background electromagnetic field, and the threshold delay time t.

7. The method of claim 1, wherein the resonance frequency of the first qubit and the resonance frequency of the second qubit is in a range of 2.5 GHz to 3.0 GHz.

8. The method of claim 1, wherein the at least one solid-state host comprises diamond.

9. The method of claim 8, wherein the point defect sites comprise Group IVA defect sites.

10. The method of claim 9, wherein the point defect sites comprise tin vacancies (SnV) or silicon vacancies (SiV).

11. The method of claim 8, wherein the point defect sites comprise nitrogen vacancies (NV).

12. A system for entangling qubits, the system comprising:
at least one solid-state host;
a first point defect site embedded in the at least one solid-state host and encoding a first qubit;
a second point defect site embedded in the at least one solid-state host and encoding a second qubit;
an electromagnetic radiation source configured to generate a background electromagnetic field to enable entanglement of the first qubit and the second qubit into an entanglement pair; and
at least one qubit state control system configured to control quantum states of the first qubit and the second qubit to entangle the first qubit and the second qubit into the entanglement pair.

13. The system of claim 12, wherein the at least one qubit state control system is configured to entangle the first qubit and the second qubit into the entanglement pair by tuning a resonance frequency of the first qubit into resonance with a resonance frequency of the background electromagnetic field for a switching time T, and after a threshold time t has elapsed, tuning a resonance frequency of the second qubit into resonance with the resonance frequency of the background electromagnetic field for the switching time T.

14. The system of claim 12, wherein tuning the resonance frequency of the first qubit or the resonance frequency of the second qubit into resonance with the resonance frequency of the background electromagnetic field comprises:
illuminating the first point defect site or the second point defect site with excitation light using a light source;
measuring a frequency of a photon emitted by the excited first point defect site or the excited second point defect site;
determining a required frequency shift based on a difference between the frequency of the emitted photon and the resonance frequency of the background electromagnetic field; and
inducing a mechanical strain in the at least one solid-state host at the first point defect site or the second point defect site based on the required frequency shift.

15. The system of claim 14, wherein the at least one qubit state control system controls at least one piezoelectric cantilever that is connected to the at least one solid-state host and is configured to induce the mechanical strain in the at least one solid-state host, wherein the voltage of the electric signal applied to the piezoelectric cantilever to induce the mechanical strain is based on the required frequency shift.

16. The system of claim 12, wherein the at least one qubit state control system is configured to initialize the first qubit into a first quantum state and to initialize the second qubit into the first quantum state.

17. The system of claim 12, wherein the at least one solid-state host is on at least one PIC chip.

18. The system of claim 12, wherein the at least one solid-state host comprises diamond.

19. The system of claim 18, wherein the point defect sites embedded in the at least one solid-state host comprise Group IVA defect sites.

20. The system of claim 18, wherein the point defect sites comprise nitrogen vacancies (NV).
